(19) United States
(12) Patent Application Publication
(10) Pub. No.: US 2018/0135170 A1
(43) Pub. Date: May 17, 2018

(54) FILM FORMING APPARATUS

(71) Applicant: TOKYO ELECTRON LIMITED, Tokyo (JP)

(72) Inventors: Noriaki FUKIAGE, Nirasaki CIty (JP); Takayuki KARAKAWA, Nirasaki City (JP); Toyohiro KAMADA, Nirasaki City (JP); Akihiro KURIBAYASHI, Nirasaki City (JP)

(21) Appl. No.: 15/809,442

(22) Filed: Nov. 10, 2017

(30) Foreign Application Priority Data
Nov. 14, 2016 (JP) 2016-221698

(51) Int. Cl. C23C 16/34; C23C 16/50; C23C 16/44; C23C 16/455; H01L 21/02; H01L 21/033

(52) U.S. Cl. CPC C23C 16/345; C23C 16/50; C23C 16/4412; C23C 16/45544; H01L 21/0337; H01L 21/0228; H01L 21/0234; H01L 21/02359; H01L 21/0332; H01L 21/0217

(57) ABSTRACT

An apparatus includes a raw material gas supply part including a discharge part for discharging a raw material gas and an exhaust port formed to surround the discharge part, reaction and modification regions formed apart from the raw material gas supply part, a reaction gas discharge part for discharging a reaction gas toward one of upstream and downstream sides, a modification gas discharge part for discharging a modification gas toward one of upstream and downstream sides, a reaction gas exhaust port formed to face an end portion of the other of the upstream and downstream sides of the reaction region, a modification gas exhaust port formed to face an end portion of the other of the upstream and downstream sides of the modification region, and plasma generation parts for reaction gas and modification gas which activate gases respectively supplied to the reaction and modification regions.

### CROSS-REFERENCE TO RELATED APPLICATION

This application is based upon and claims the benefit of priority from Japanese Patent Application No. 2016-221698, filed on Nov. 14, 2016, the entire contents of which are incorporated herein by reference.

### TECHNICAL FIELD

The present disclosure relates to a film forming apparatus for forming a silicon nitride film on a substrate using a raw material gas containing silicon and a nitrogen-containing gas.

### BACKGROUND

In semiconductor manufacturing processes, for example, a film forming process is carried out to form a silicon nitride film (hereinafter, also referred to as an “SiN film”) as a hard mask for etching, a spacer insulating film, a sealing film or the like on a substrate. The SiN film of this application is required to have, for example, a low etching rate against, e.g., a hydrofluoric acid solution or plasma resistance, thus requiring high denseness. For example, a film forming apparatus that forms an SiN film by an atomic layer deposition (ALD) method is known.

In such a film forming apparatus, a film forming process is performed in a process chamber by rotating (revolving) a mounting table around an axial line such that a substrate mounting region formed in the mounting table sequentially passes through a first region and a second region inside the process chamber. In the first region, a silicon-containing gas as a raw material gas is supplied from an injection part of a first gas supply part so that silicon (Si) is adsorbed onto the substrate. An unnecessary raw material gas is exhausted from an exhaust port formed to surround the injection part. In the second region, a reaction gas such as a nitrogen (N₂) gas or an ammonia (NH₃) gas is supplied from a third gas supply part. These gases are excited, and Si adsorbed onto the substrate is nitrided by active species of the reaction gas to form an SiN film. In the second region, an exhaust port is formed to allow the unnecessary reaction gas to be exhausted therethrough.

A dense SiN film is formed by the ALD method. Depending on the intended use, for example, in a case where the SiN film is used as a hard mask, it is required to further enhance the denseness of the film. Thus, there is a demand for a method of forming a high quality SiN film having a low etching rate at a fast deposition rate.

### SUMMARY

The present disclosure provides some embodiments of a technique of forming a silicon nitride film using a raw material gas containing silicon and a nitrogen-containing gas, which is capable of forming a high quality silicon nitride film having a low etching rate at a high deposition rate.

According to one embodiment of the present disclosure, there is provided a film forming apparatus for forming a silicon nitride film on a substrate by revolving the substrate mounted on a rotary table inside a vacuum vessel while rotating the rotary table and supplying a raw material gas containing silicon and a nitrogen-containing gas to each of a plurality of regions formed to be separated from each other on the rotary table in a circumferential direction, including: a raw material gas supply part installed to face the rotary table and including a discharge part configured to discharge the raw material gas and an exhaust port configured to surround the discharge part; a reaction region and a modification region of the plurality of regions which are formed apart from the raw material gas supply part in a rotational direction of the rotary table and are formed apart from each other in the rotational direction of the rotary table; a reaction gas discharge part installed at an end portion of one of an upstream side and a downstream side of the reaction region and configured to discharge a reaction gas containing the nitrogen-containing gas toward the other of the upstream side and the downstream side of the reaction region; a modification gas discharge part installed at an end portion of one of an upstream side and a downstream side of the modification region and configured to discharge a modification gas containing a hydrogen gas toward the other of the upstream side and the downstream side of the modification region; a reaction gas exhaust port formed at an outer side of the rotary table and at a position facing an end portion of the other of the upstream side and the downstream side of the reaction region; a modification gas exhaust port formed at an outer side of the rotary table and at a position facing an end portion of the other of the upstream side and the downstream side of the modification region; and a plasma generation part for reaction gas and a plasma generation part for modification gas which are configured to activate gases respectively supplied to the reaction region and the modification region, wherein each of the reaction gas discharge part and the modification gas discharge part is constituted by a gas injector having discharge ports formed along a longitudinal direction, and disposed to intersect with a passage region of the plurality of regions through which the substrate mounted on the rotary table passes.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic longitudinal sectional view of a film forming apparatus according to a first embodiment of the present disclosure.

FIG. 2 is a transverse plan view of the film forming apparatus.

FIG. 3 is a longitudinal sectional view of a gas supply/exhaust unit installed in the film forming apparatus.

FIG. 4 is a bottom view of the gas supply/exhaust unit.

FIG. 5 is a longitudinal sectional view schematically illustrating a portion of the film forming apparatus.

FIG. 6 is a side view illustrating an example of a reaction gas injector installed in the film forming apparatus.

FIG. 7 is a cross sectional view of the reaction gas injector.

FIG. 8 is a longitudinal sectional view illustrating the film forming apparatus.

FIG. 9 is a plan view illustrating a state of the film forming apparatus.

FIG. 10 is a transverse plan view illustrating a film forming apparatus according to a second embodiment of the present disclosure.

FIG. 11 is a longitudinal sectional view schematically illustrating a portion of the film forming apparatus.

FIG. 12 is a plan view illustrating a state of the film forming apparatus.

FIG. 13 is a longitudinal sectional view illustrating another example of the film forming apparatus.

FIG. 14 is a longitudinal sectional view illustrating another example of the film forming apparatus.

FIG. 15 is a longitudinal sectional view illustrating another example of the film forming apparatus.

FIG. 16 is a transverse plan view illustrating a comparative apparatus for evaluation test.

FIG. 17 is a characteristic diagram illustrating an etching rate.

FIG. 18 is a characteristic diagram illustrating a deposition rate.

FIG. 19 is a characteristic diagram illustrating a film thickness distribution.

FIG. 20 is a characteristic diagram illustrating a film thickness distribution.

FIG. 21 is a characteristic diagram illustrating a film thickness distribution.

FIG. 22 is a characteristic diagram illustrating a film thickness distribution.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

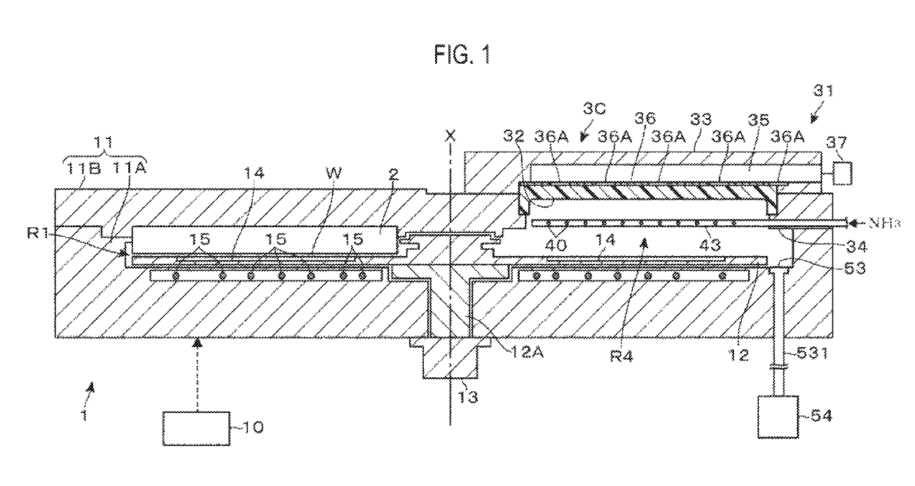

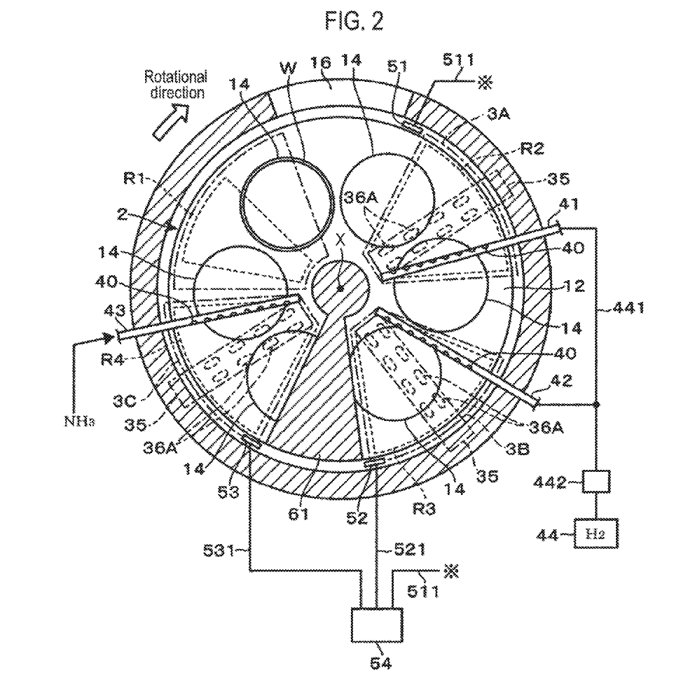

A film forming apparatus 1 according to a first embodiment of the present disclosure will be described with reference to each of a longitudinal sectional view of FIG. 1 and a transverse plan view of FIG. 2. The film forming apparatus 1 forms an SiN film on a surface of a semiconductor wafer (hereinafter, referred to as a “wafer”) W as a substrate by an atomic layer deposition (ALD) method. The SiN film is, for example, a hard mask for etching. In this specification, the silicon nitride film will be described as SiN regardless of stoichiometry of Si and N. Therefore, the description of SiN includes, for example, Si₃N₄.

In FIG. 1, reference numeral 11 denotes a flat vacuum vessel (process vessel) having a substantially circular shape. The vacuum vessel 11 includes a vessel main body 11A constituted by a sidewall and a bottom portion, and a ceiling plate 11B. In FIG. 1, reference numeral 12 denotes a circular rotary table horizontally installed inside the vacuum vessel 11. In FIG. 1, reference numeral 12A denotes a supporting part that supports a central portion of a rear surface of the rotary table 12. In FIG. 1, reference numeral 13 denotes a rotary mechanism which rotates the rotary table 12 clockwise in a plan view in its circumferential direction through the supporting part 12A during a film forming process. In FIG. 2, reference numeral X denotes a rotation axis of the rotary table 12.

Six circular recesses 14 are formed in an upper surface of the rotary table 12 along the circumferential direction (rotational direction) of the rotary table 12. The wafers W are stored in respective recesses 14. That is to say, each wafer W is mounted on the rotary table 12 so as to be revolved with the rotation of the rotary table 12. In FIG. 1, reference numeral 13 denotes a plurality of heaters installed concentrically at the bottom portion of the vacuum vessel 11 to heat the wafers W mounted on the rotary table 12. In FIG. 2, reference numeral 16 denotes a transfer port through which the wafer W is transferred and which is opened in the sidewall of the vacuum vessel 11. The transfer port 16 is configured to be opened and closed by a gate valve (not shown). The wafer W is delivered between the outside of the vacuum vessel 11 and the inside of the recess 14 by a substrate transfer mechanism (not shown) through the transfer port 16.

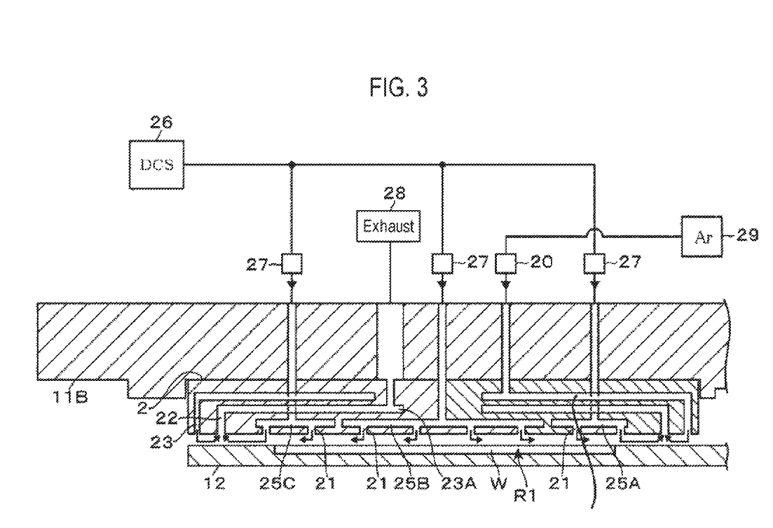

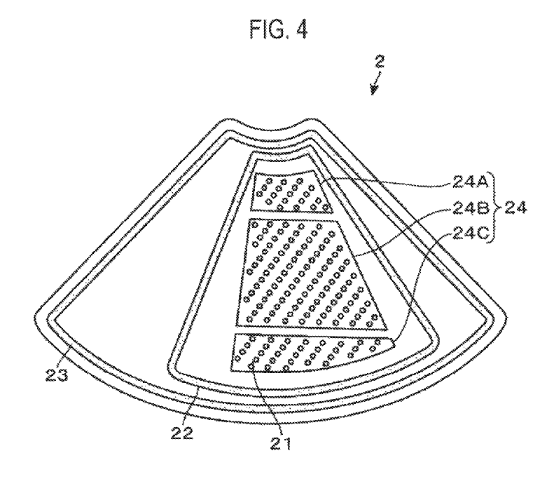

A gas supply/exhaust unit 2 used as a raw material gas supply part, a first modification region R2, a second modification region R3, and a reaction region R4 are sequentially installed on the rotary table 12 toward a downstream side of the rotary table 12 in the rotational direction of the rotary table 12. The gas supply/exhaust unit 2 corresponds to the raw material gas supply part which supplies a raw material gas and includes a discharge part and an exhaust port. Hereinafter, the gas supply/exhaust unit 2 will be described with reference to FIG. 3 which is a longitudinal sectional view and FIG. 4 which is a bottom view. The gas supply/exhaust unit 2 is formed in a fan shape extending from the central side of the rotary table 12 toward the peripheral side of the rotary table 12 in the circumferential direction of the rotary table 12 when viewed from the top. A lower surface of the gas supply/exhaust unit 2 is close to the upper surface of the rotary table 12 in a facing manner.

Gas discharge ports 21 which constitute a discharging part, an exhaust port 22, and a purge gas discharge port 23 are opened in the lower surface of the gas supply/exhaust unit 2. To assure easier identification, in FIG. 4, each of the exhaust port 22 and the purge gas discharge port 23 is indicated by a plurality of dots. The plurality of gas discharge ports 21 is arranged in a fan-shaped region 24 inward of the peripheral portion of the lower surface of the gas supply/exhaust unit 2. A DCS gas, which is a raw material gas containing silicon (Si) for forming an SiN film, is discharged downward from the gas discharge ports 21 in a shower shape during the rotation of the rotary table 12 in the film forming process, and is supplied to the entire surface of the wafer W. The raw material gas containing silicon is not limited to DCS, and for example, hexachlorodisilane (HCD), tetrachlorosilane (TCS) or the like may be used.

In the fan-shaped region 24, three zones 24A, 24B, and 24C are defined from the central side of the rotary table 12 toward the peripheral side thereof. Gas flow passages 25A, 25B, and 25C partitioned from one another are formed in the gas supply/exhaust unit 2 so that the DCS gas can be independently supplied to each of the gas discharge ports 21 formed in the respective zones 24A, 24B, and 24C. A downstream end of each of the gas flow passages 25A, 25B, and 25C correspond to each of the gas discharge ports 21.

Furthermore, each of upstream sides of the gas flow passages 25A, 25B, and 25C is connected to a DCS gas supply source 26 via a respective pipe. A gas supply device 27 constituted by a valve and a mass flow controller is installed in each pipe. The supply/cutoff and flow rate of the DCS gas from the DCS gas supply source 26 to each of the gas flow passages 25A, 25B, and 25C are controlled by the respective gas supply device 27. In addition, each gas supply device other than the gas supply device 27, which will be described later, is configured similarly to the gas supply device 27 and controls the supply/cutoff and flow rate of the gas to the downstream side.

Next, each of the exhaust port 22 and the purge gas discharge port 23 will be described. The exhaust port 22 and the purge gas discharge port 23 are annularly opened at the peripheral portion of the lower surface of the gas supply/exhaust unit 2 so as to surround the fan-shaped region 24 and to face the upper surface of the rotary table 12. The purge gas discharge port 23 is located outside the exhaust port 22. A region inward of the exhaust port 22 on the rotary table 12 is defined as an adsorption region R1 in which DCS is adsorbed onto the surface of the wafer W. The purge gas discharge port 23 discharges, for example, an argon (Ar) gas as a purge gas onto the rotary table 12.

In the course of the film forming process, the discharge of the raw material gas from the gas discharge ports 21, the exhaust of the gas from the exhaust port 22, and the discharge of the purge gas from the purge gas discharge port 23 are performed at the same time. Thus, as indicated by arrows in FIG. 3, the raw material gas and the purge gas discharged toward the rotary table 12 flow toward the exhaust port 22 along the upper surface of the rotary table 12 and are exhausted from the exhaust port 22. By performing the discharge and exhaust of the purge gas in this manner, the atmosphere in the adsorption region R1 is separated from the external atmosphere so that the raw material gas can be limitedly supplied to the adsorption region R1. That is to say, it is possible to suppress the DCS gas supplied to the adsorption region R1 and each gas supplied to the outside of the adsorption region R1 by plasma forming units 3A to 3C (to be described later) and active species of each gas, from being mixed with each other. Thus, as described hereinbelow, it is possible to perform the film forming process on the wafer W by the ALD method. In addition to the role of separating the atmosphere in this manner, the purge gas also has the role of removing the DCS gas excessively adsorbed onto the wafer W from the wafer W.

In FIG. 3, reference numerals 23A and 23B denote gas flow passages formed in the gas supply/exhaust unit 2 and partitioned from each other, and are also formed to be partitioned from the flow passages 25A to 25C of the raw material gas. An upstream end of the gas flow passage 23A is connected to the exhaust port 22 and a downstream end of the gas flow passage 23A is connected to an exhaust device 28, thereby performing the gas exhaust from the exhaust port 22 by the exhaust device 28. Furthermore, a downstream end of the gas flow passage 23B is connected to the purge gas discharge port 23 and an upstream end of the gas flow passage 23B is connected to an Ar gas supply source 29. A gas supply device 20 is installed in a pipe which connects the gas flow passage 23B and the Ar gas supply source 29.

In the first modification region R2, the second modification region R3, and the reaction region R4, a first plasma forming unit 3A, a second plasma forming unit 3B, and a third plasma forming unit 3C for activating gases supplied to the respective regions are installed. Each of the first plasma forming unit 3A and the second plasma forming unit 3B constitutes a plasma generation part for modification gas and the third plasma forming unit 3C constitutes a plasma generation part for reaction gas. Each of the first to third plasma forming units 3A to 3C is similar to each other in configuration, and here, the third plasma forming unit 3C representatively illustrated in FIG. 1 will be described. The third plasma forming unit 3C supplies a gas for plasma formation onto the rotary table 12 and also supplies a microwave to the gas to generate plasma on the rotary table 12. The third plasma forming unit 3C includes an antenna 31 for supplying the microwave. The antenna 31 includes a dielectric plate 32 and a waveguide 33 made of metal.

The dielectric plate 32 has a substantially fan shape that widens from the central side toward the peripheral side of the rotary table 12 in a plan view. A substantially fan-shaped through hole is formed in the ceiling plate 11B of the vacuum vessel 11 so as to correspond to the shape of the dielectric plate 32. An inner peripheral surface of a lower end portion of the through hole slightly protrudes toward a central portion of the through hole to form a supporting part 34. The dielectric plate 32 closes the through hole from the upper side and is installed to face the rotary table 12. The peripheral portion of the dielectric plate 32 is supported by the supporting part 34.

The waveguide 33 is installed on the dielectric plate 32, and has an inner space 35 extending along the ceiling plate 11B. In FIG. 1, reference numeral 36 denotes a slot plate constituting a lower side of the waveguide 33. The slot plate is installed to make contact with the dielectric plate 32, and has a plurality of slot holes 36A. An end portion of the waveguide 33 at the central side of the rotary table 12 is closed, and the other end portion of the waveguide 33 at the peripheral side of the rotary table 12 is connected to a microwave generator 37. The microwave generator 37 supplies a microwave of, for example, about 2.45 GHz to the waveguide 33.

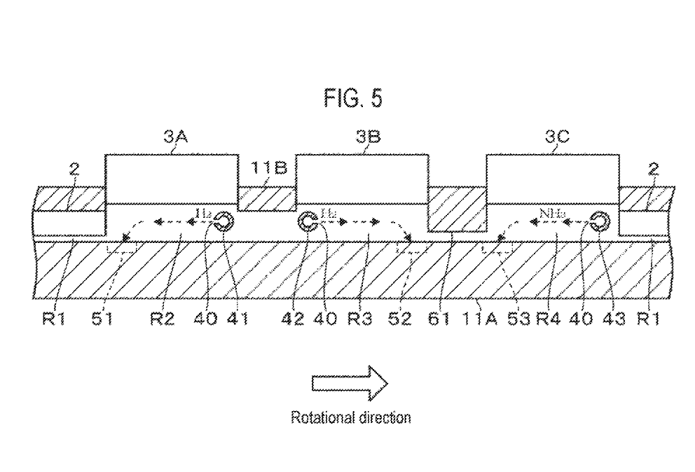

As illustrated in FIGS. 2 and 5, a first gas injector 41 constituting a first modification gas discharge part for discharging a modification gas containing a hydrogen (H₂) gas toward an upstream side is installed at an end portion of a downstream side of the first modification region R2. Furthermore, a second gas injector 42 constituting a second modification gas discharge part for discharging a modification gas containing an H₂ gas toward a downstream side is installed at an end portion of an upstream side of the second modification region R3. In addition, a reaction gas injector 43 constituting a reaction gas discharge part for discharging a reaction gas containing an NH₃ gas as a nitrogen-containing gas toward an upstream side is installed at an end portion of a downstream side of the reaction region R4. The first and second gas injectors 41 and 42 and the reaction gas injector 43 are similar to each other in configuration and may sometimes be referred to as the gas injectors 41, 42, and 43 below. Hereinafter, an example in which the H₂ gas is used as the modification gas and the NH₃ gas is used as the reaction gas will be described.

As illustrated in FIGS. 1, 2, 6, and 7, for example, the first and second gas injectors 41 and 42, and the reaction gas injector 43 are each constituted by an elongated tubular body with a leading end closed. Each of the gas injectors 41, 42, and 43 is installed in the sidewall of the vacuum vessel 11 so as to extend horizontally from the sidewall of the vacuum vessel 11 toward the central region thereof, and is disposed to intersect with a passage region of the wafer W on the rotary table 12. The term “horizontally” used herein encompasses “substantially horizontally” when viewed with human eyes.

Gas discharge ports 40 are formed in each of the gas injectors 41, 42, and 43 along a longitudinal direction, respectively. As in the reaction gas injector 43 illustrated in FIG. 7 as an example, the orientations of the gas discharge ports 40 (directions in which a gas is discharged) are set to discharge a gas between an upwardly 45 degree-inclined orientation as indicated by a dashed dotted line L1 and a downwardly 45-degree inclined orientation as indicated by a dashed dotted line L2 with respect to a direction (i.e., a horizontal direction) (a direction indicated by a dotted line L in FIG. 7) parallel to the upper surface of the rotary table 12, namely toward the horizontal direction in this example. For example, in each of the gas injectors 41, 42 and 43, the gas discharge ports 40 are formed in a region that covers the passage region of the wafer W on the rotary table 12.

As illustrated in FIG. 2, for example, each of the first gas injector 41 and the second gas injector 42 is connected to an H₂ gas supply source 44 via a pipe system 441 including a gas supply device 442 installed therein. The gas supply device 442 is configured to control the supply/cutoff and flow rate of the H₂ gas from the H₂ gas supply source 44 to each of the first gas injector 41 and the second gas injector 42.

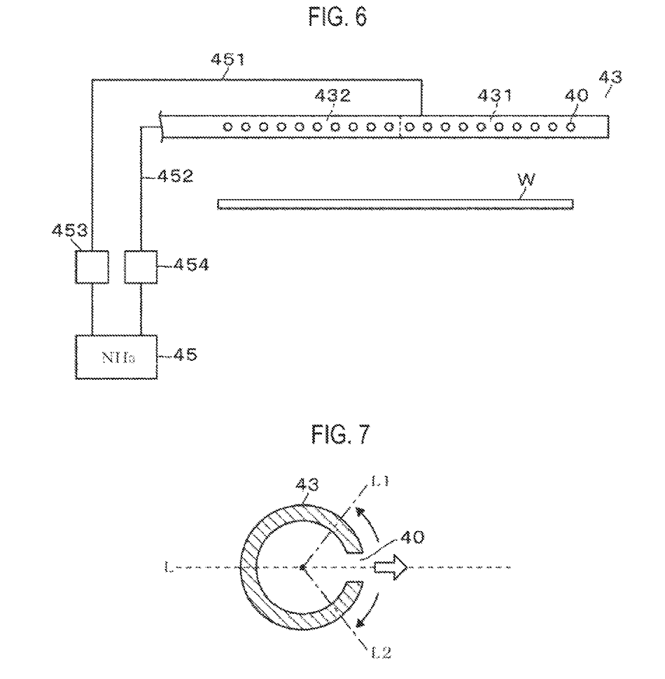

In the reaction gas injector 43 of this example, for example, as illustrated in FIG. 6, a gas discharge region in which the gas discharge ports 40 are formed is divided into a plurality of, e.g., two regions, in a longitudinal direction of the reaction gas injector 43. By a first gas discharge region 431 defined at a leading end of the reaction gas injector 43 and a second gas discharge region 432 defined at a base end of the reaction gas injector 43, an internal gas flow space of the reaction gas injector 43 is partitioned. The first gas discharge region 431 is connected to an NH₃ gas supply source 45 via a pipe system 451 including a gas supply device 453 installed therein. The second gas discharge region 432 is connected to the NH₃ gas supply source 45 via a pipe system 452 including a gas supply device 454 installed therein. The gas supply devices 453 and 454 are configured to control the supply/cutoff and flow rate of the NH₃ gas from the gas supply source 45 to the reaction gas injector 43. Thus, the NH₃ gas can be discharged at different flow rates from the first gas discharge region 431 and the second gas discharge region 432. The gas discharge region of the reaction gas injector 43 may not be divided in the longitudinal direction.

In this example, the first and second gas injectors 41 and 42, and the reaction gas injector 43 are installed below the first to third plasma forming units 3A to 3C, respectively. In some embodiments, for example, the first gas injector 41 may be installed below a region adjacent to the downstream side of the first plasma forming unit 3A in the rotational direction. Similarly, the second gas injector 42 may be installed below a region adjacent to the upstream side of the second plasma forming unit 3B in the rotational direction, and the reaction gas injector 43 may be installed below a region adjacent to the downstream side of the third plasma forming unit 3C in the rotational direction.

In the first and second modification regions R2 and R3, the microwave supplied to the waveguide 33 reaches the dielectric plate 32 through the slot holes 36A of the slot plate 36 and is supplied to the H₂ gas discharged below the dielectric plate 32 to limitedly form plasma in the first and second modification regions R2 and R3 below the dielectric plate 32. Even in the reaction region R4, plasma of the NH₃ gas is limitedly formed in the reaction region R4 below the dielectric plate 32.

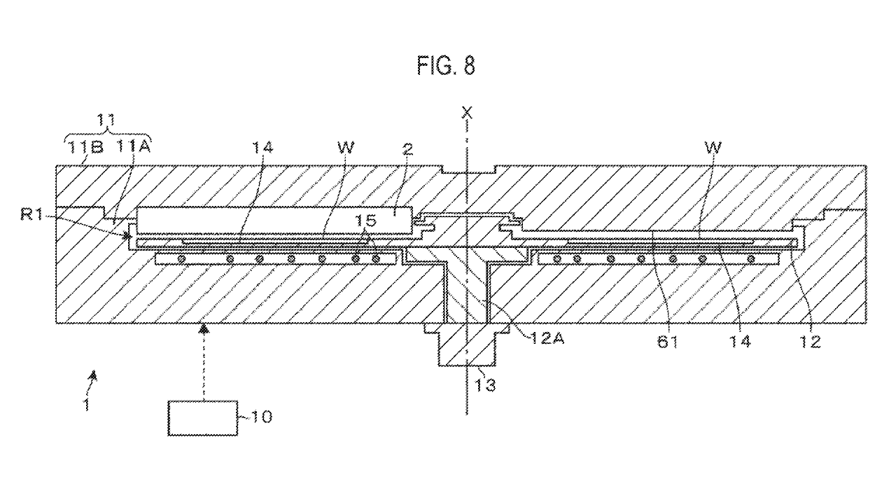

As illustrated in FIGS. 2, 5, and 8, a separation region 61 is formed between the second modification region R3 and the reaction region R4. A ceiling surface of the separation region 61 is set to become lower than a ceiling surface of each of the second modification region R3 and the reaction region R4. As illustrated in FIG. 2, the separation region 61 has a fan shape widening from the central side of the rotary table 12 toward a peripheral side thereof in the circumferential direction of the rotary table 12 in a plan view. A lower surface of the separation region 61 is close to the upper surface of the rotary table 12 in a facing manner. A gap between the lower surface of the separation region 61 and the upper surface of the rotary table 12 is set to, for example, 3 mm, in order to suppress a gas from entering below the separation region 61. The lower surface of the separation region 61 may also be set at a height equal to the lower surface of the ceiling plate 11B.

Furthermore, as illustrated in FIG. 2, a first exhaust port 51, a second exhaust port 52, and a third exhaust port 53 are respectively formed at an outer side of the rotary table 12 and at positions facing the end portion of the upstream side of the first modification region R2, the end portion of the downstream side of the second modification region R3, and the end portion of the upstream side of the reaction region R4. The first exhaust port 51 is to exhaust the H₂ gas discharged from the first gas injector 41 in the first modification region R2. The second exhaust port 52 is to exhaust the H₂ gas discharged from the second gas injector 42 in the second modification region R3 and is formed near the upstream side of the separation region 61 in the rotational direction. Furthermore, the third exhaust port 53 is to exhaust the NH₃ gas discharged from the reaction gas injector 43 in the reaction gas region R4 and is formed near the downstream side of the separation region 61 in the rotational direction.

As in the third exhaust port 53 representatively illustrated in FIG. 1, the first to third exhaust ports 51 to 53 are formed to be upwardly opened outward of the rotary table 12 in the vessel main body 11A of the vacuum vessel 11. The openings of the first to third exhaust ports 51 to 53 are located lower than the rotary table 12. In addition, in FIG. 1, the reaction gas injector 43 and the third exhaust port 53 of the reaction region R4 are illustrated side by side, although their positions in the circumferential direction deviate. The first exhaust port 51, the second exhaust port 52, and the third exhaust port 53 are connected to, for example, a common exhaust device 54 through exhaust paths 511, 521, and 531, respectively.

An exhaust amount adjustment part (not shown) is installed in each of the exhaust paths 511, 521, and 531 so that exhaust amounts of gases from the first to third exhaust ports 51 to 53 can be, for example, individually adjusted by the exhaust device 54. In some embodiments, the exhaust amounts of gases from the first to third exhaust ports 51 to 53 may be adjusted by a common exhaust amount adjustment part. Thus, in the first and second modification regions R2 and R3 and the reaction region R4, the gases discharged from the respective gas injectors 41 to 43 are exhausted and removed from the first to third exhaust ports 51 to 53. As a result, a vacuum atmosphere of a pressure corresponding to the exhaust amounts is formed inside the vacuum vessel 11.

As illustrated in FIG. 1, a control part 10 configured as a computer is installed in the film forming apparatus 1. A program is stored in the control part 10. The program incorporates a group of steps so as to send control signals to respective parts of the film forming apparatus 1 and to control operations of the respective parts, thus executing a film forming process described hereinbelow. Specifically, the number of rotations of the rotary table 12 performed by the rotary mechanism 13, the flow rate and supply/cutoff of each gas performed by each gas supply device, the exhaust amount of gas performed by each of the exhaust devices 28 and 54, the supply/cutoff of the microwave from the microwave generator 37 to the antenna, the supply of power to the heater 15 or the like is controlled by the program. That is to say, the control of the supply of power to the heater 15 corresponds to controlling a temperature of the wafer W, and the control of the exhaust amount of gas performed by the exhaust device 54 corresponds to controlling an internal pressure of the vacuum vessel 11. This program is installed on the control part 10 from a storage medium such as a hard disk, a compact disc, a magneto-optical disc, a memory card, or the like.

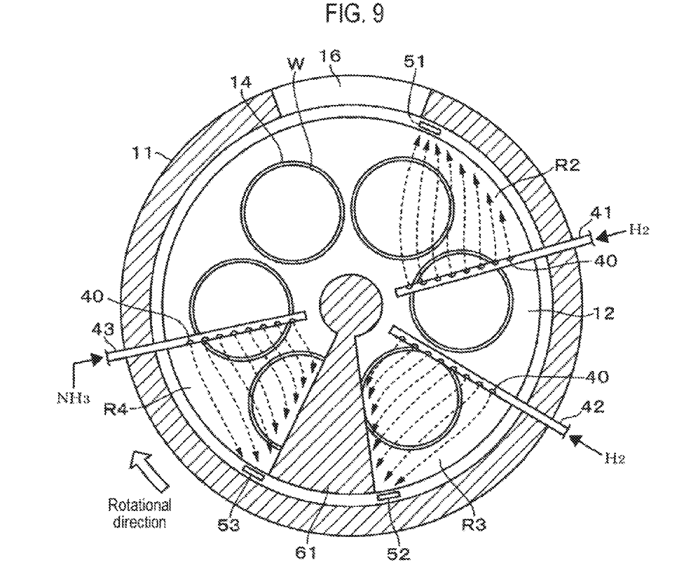

Hereinafter, the film forming process performed by the film forming apparatus 1 will be described with reference to FIG. 9 schematically illustrating a state in which a gas is supplied in each part within the vacuum vessel 11. First, six wafers W are transferred to the respective recesses 14 of the rotary table 12 by the substrate transfer mechanism and the gate valve installed near the transfer port 16 of the wafer W is closed to hermetically seal the interior of the vacuum vessel 11. The wafers W mounted in the recesses 14 are heated by the heaters 15 to a predetermined temperature. Then, the interior of the vacuum vessel 11 is exhausted from the first to third exhaust ports 51, 52, and 53 so as to become a vacuum atmosphere of a predetermined pressure, and the rotary table 12 is rotated at, for example, 10 to 30 rpm.

Subsequently, in the first to third plasma forming units 3A to 3C, the H₂ gas is discharged at a flow rate of, for example, 4 litter(l)/min from each of the first gas injector 41 and the second gas injector 42, and the NH₃ gas is discharged at a flow rate of a total of 1,000 to 4,000 ml/min(sccm), for example, 2,000 ml/min, from the reaction gas injector 43, for example, the first gas discharge region 431 and the second gas discharge region 432 (see FIG. 6).

In the first modification region R2, the H₂ gas is discharged from the first gas injector 41 disposed at the end portion of the downstream side toward the upstream side in the horizontal direction. Since the H₂ gas flows toward the first exhaust port 51 formed at the upstream end, the H₂ gas flows to widely spread throughout the first modification region R2. Also in the second modification region R3, the H₂ gas is discharged from the second gas injector 42 disposed at the end portion of the upstream side toward the downstream side in the horizontal direction. Since the H₂ gas flows toward the second exhaust port 52 at the downstream end, the H₂ gas flows to widely spread throughout the second modification region R3. Furthermore, for example, a portion of the H₂ gas may be introduced into the separation region 61. However, since the ceiling portion of the separation region 61 is located at a relatively low position and has small conductance, the portion of the H₂ gas is returned by virtue of an attractive force of the second exhaust port 52 and exhausted into the second exhaust port 52.

In the reaction region R4, the NH₃ gas is discharged from the reaction gas injector 43 disposed at the end portion of the downstream side toward the upstream side in the horizontal direction. Since the NH₃ gas flows toward the third exhaust port 53 formed at the upstream side, the NH₃ gas flows to widely spread throughout the reaction region R4. For example, a portion of the NH₃ gas may be introduced into the separation region 61. However, since the separation region 61 has small conductance, the portion of the NH₃ gas is returned by virtue of an attractive force of the third exhaust port 53 and exhausted into the third exhaust port 53. Thus, regions through which the NH₃ gas and the H₂ gas flow are separated from each other between the first and second modification regions R2 and R3 and the reaction region R4, which suppresses the NH₃ gas and the H₂ gas from being mixed with each other.

In addition, the microwave is supplied from the microwave generator 37. The H₂ gas or the NH₃ gas is plasmarized by the microwave to form plasma P1 of the H₂ gas in the first and second modification regions R2 and R3 and plasma P2 of the NH₃ gas in the reaction region R4, respectively. If each wafer W passes through the reaction region R4 with the rotation of the rotary table 12, active species such as radicals or the like containing nitrogen (N) generated from the NH₃ gas, which constitute the plasma P2, are supplied to the surface of each wafer W. Thus, the surface layer of the wafer W is nitrided to form a nitride film.

In the gas supply/exhaust unit 2, a DCS gas is discharged at a predetermined flow rate from the gas discharge ports 21 and an Ar gas is discharged at a predetermined flow rate from the purge gas discharge port 23, and an exhaust operation is performed through the exhaust port 22. Furthermore, in the first and second modification regions R2 and R3 and the reaction region R4, the plasma P1 of the H₂ gas or the plasma P2 of the NH₃ gas is continuously formed.

In this manner, each gas is supplied and the plasma P1 or P2 is formed, while the interior of the vacuum vessel 11 has a predetermined pressure of, for example, 66.5 to 665 Pa (5 Torr). When the wafer W is located in the adsorption region R1 with the rotation of the rotary table 12, the DCS gas as a raw material gas containing silicon is supplied to and adsorbed onto the surface of the nitride film. Subsequently, with the further rotation of the rotary table 12, the wafer W is moved outward of the adsorption region R1, and a purge gas is supplied to the surface of the wafer W to remove a surplus DCS gas adsorbed onto the surface of the wafer W.

Subsequently, when the wafer W reaches the reaction region R4 with the rotation of the rotary table 12, the active species of the NH₃ gas contained in the plasma are supplied to the wafer W and reacts with the DCS gas to form an SiN layer on the nitride film in an island shape. In addition, when the wafer W reaches the first and second modification regions R2 and R3 with the rotation of the rotary table 12, H is bonded to a dangling bond of the SiN film by the active species of the H₂ gas contained in the plasma to modify the SiN film to a dense film. Since the DCS gas contains chlorine (Cl), when the DCS gas is used as a raw material gas, there is a possibility that a chlorine component will be introduced as an impurity into the formed SiN film. Due to this, the chlorine component contained in the thin film is desorbed by the action of the active species of the H₂ gas by irradiating the plasma of the H₂ gas in the first and second modification regions R2 and R3, thus modifying the SiN film to a more pure (dense) nitride film.

In this manner, the wafer W is sequentially repeatedly moved to the adsorption region R1, the first and second modification regions R2 and R3 and the reaction region R4 and sequentially repeatedly supplied with the DCS gas, the active species of the H₂ gas, and the active species of the NH₃ gas so that each SiN layer of an island shape spreadly grows while being modified. Subsequently, the rotary table 12 continues to be rotated, SiN is deposited on the surface of the wafer W, and a thin layer grows to form the SiN film. That is to say, when the film thickness of the SiN film is increased to form the SiN film having a desired film thickness, for example, the discharge and exhaust of each gas in the gas supply/exhaust unit 2 are stopped. Further, the supply of the H₂ gas and the supply of electric power in the first and second plasma forming units 3A and 3B and the supply of the NH₃ gas and the supply of electric power in the third plasma forming unit 3C are stopped and the film forming process is completed. The wafers W which have been subjected to the film forming process, are unloaded from the film forming apparatus 1 by the transfer mechanism.

According to the film forming apparatus 1 described above, the H₂ gas supplied to the first modification region R2 and the second modification region R3 is respectively exhausted from the first exhaust port 51 and the second exhaust port 52 installed in the first modification region R2 and the second modification region R3, and the NH₃ gas supplied to the reaction region R4 is exhausted from the third exhaust port 53 installed in the reaction region R4. Therefore, so-called dedicated exhaust performance in each of the regions R2, R3, and R4 is high, which suppresses the H₂ gas and the NH₃ gas from being mixed between the first modification region R2 and the second modification region R3 and the reaction region R4. Thus, although the supply flow rate of the NH₃ gas to the reaction region R4 is increased, the spreading of the NH₃ gas to the first modification region R2 and the second modification region R3 is suppressed. This allows the modification process by the active species of the H₂ gas to be performed with high efficiency, thus enhancing the denseness of the SiN film and securing a low etching rate. Furthermore, in the reaction region R4, a deposition rate is increased with an increase in the flow rate of the NH₃ gas. As a result it is possible to form a high quality SiN film having a low etching rate at a fast deposition rate.

In the case where the common exhaust port is formed in the supply region of the H₂ gas and the supply region of the NH₃ gas as in the related art, if the supply flow rate of the NH₃ gas is increased, the NH₃ gas may be spread even to the supply region of the H₂ gas, causing the H₂ gas and the NH₃ gas to be easily mixed. Thus, if the supply flow rate of the NH₃ gas is increased to increase a deposition rate, as is clear from the evaluation tests described hereinbelow, the modification efficiency in the modification regions is lowered and a film having a high etching rate may be formed. Therefore, in the related art apparatus, in order to secure a low etching rate, the flow rate of the NH₃ gas is required to be set at about 100 ml/min. This makes it difficult to meet both the increase in a deposition rate and the decrease in an etching rate in the formation of the SiN film.

In contrast, in the aforementioned embodiment, it was confirmed from the evaluation tests described hereinbelow that, when the flow rate of the NH₃ gas is set at 300 ml/min or more, it is possible to form an SiN film having a low etching rate at a fast deposition rate, compared with the related art. Thus, the aforementioned embodiment may be regarded as an effective technique when the flow rate of the NH₃ gas is 300 ml/min or more.

Furthermore, the reaction gas injector 43 is installed at the downstream side of the reaction region R4 in the rotational direction, the gas discharge ports 40 are formed to discharge a gas toward the upstream side of the reaction region R4, and the third exhaust port 53 is formed at the upstream side of the reaction region R4 in the rotational direction. Therefore, the NH₃ gas discharged from the reaction gas injector 43 flows in a direction away from the adsorption region R1 of Si defined at the downstream side of the reaction region R4 in the rotational direction, which suppresses the spreading of the NH₃ gas to the adsorption region R1.

In addition, the first modification region R2 and the second modification region R3 are adjacent to each other in the rotational direction. In the first modification region R2, the H₂ gas is discharged from the first gas injector 41 installed at a position closer to the second modification region R3 toward the first exhaust port 51 formed at the opposite side of the second modification region R3. Meanwhile, in the second modification region R3, the H₂ gas is discharged from the second gas injector 42 installed at a position closer to the first modification region R2 side toward the second exhaust port 52 formed at the opposite side of the first modification region R2. Thus, in the large modification region including the first and second modification regions R2 and R3, the gases are respectively discharged from the central portion in the rotational direction toward the upstream side and the downstream side. It is therefore possible to widely distribute the H₂ gas evenly over a large range. As a result, the modification process can be sufficiently performed in the first and second modification regions R2 and R3, obtaining a high modification effect.

Furthermore, the second modification region R3 and the reaction region R4 are adjacent to each other in the rotational direction. In the second modification region R3, the second exhaust port 52 is formed at a position closer to the reaction region R4. In the reaction region R4, the third exhaust port 53 is formed at a position closer to the second modification region R3. As described above, the second and third exhaust ports 52 and 53 tailored to the respective regions R3 and R4 are formed between the regions R3 and R4 adjacent to each other, respectively. Thus, even if the H₂ gas and the NH₃ gas try to move toward the adjacent regions R3 and R4 sides, respectively, since the two exhaust ports are respectively formed between the regions R3 and R4 adjacent to each other, the H₂ gas and the NH₃ gas are exhausted to be drawn to the respective exhaust ports. This keeps different gases from spreading into the second modification region R3 or the reaction region R4.

In addition, the separation region 61 is defined between the second modification region R3 and the reaction region R4. When the gases try to move to the adjacent regions R3 and R4, as described above, the gases are returned to the second and third exhaust ports 52 and 53 by virtue of an attractive force of the second exhaust port 52 and the third exhaust port 53 due to the small conductance to the separation region 61. Thus, in the second modification region R3 or the reaction region R4, the spreading of different gases is further suppressed.

Furthermore, the gas discharge ports 40 of the first and second gas injectors 41 and 42 and the reaction gas injector 43 are formed to discharge a gas in the horizontal direction. Therefore, in the first and second modification regions R2 and R3 and the reaction region R4, the gases rapidly flow toward the first to third exhaust ports 51 to 53 so that they are evenly and widely distributed and exhausted in the respective regions R2 to R4.

Also as described above, since the H₂ gas and the NH₃ gas are kept from being mixed with each other, the film thickness can be controlled as is clear from the evaluation tests described hereinbelow. That is to say, in the reaction region R4, when the gas flow rates of the first gas discharge region 431 and the second gas discharge region 432 of the reaction gas injector 43 are changed, the change in the flow rates is reflected as it is in the film thickness. Thus, it is possible to control a film thickness of the wafer W in the radial direction by adjusting the gas flow rate of the reaction gas injector 43 in the longitudinal direction.

In addition, the first gas injector 41 and the first exhaust port 51 are located at the downstream side and the upstream side of the first modification region R2 in the rotational direction, respectively. The second gas injector 42 and the second exhaust port 52 are located at the upstream side and the downstream side of the second modification region R3 in the rotational direction, respectively. In this manner, the gas injectors 41 and 42 and the first and second exhaust ports 51 and 52 are located to face each other in the rotational direction in the first and second modification regions R2 and R3, respectively. Thus, a period of time during which the H₂ gas stays in the plasma spaces of the modification regions R2 and R3 is lengthened. Therefore, the Ar gas and the NH₃ gas are kept from being mixed. Further, even if a partial pressure of the H₂ gas is high or even if the flow rate of the H₂ gas is low, the modification process can be sufficiently performed. In this manner, in the apparatus of the present disclosure, it is possible to promote an increase in the flow rate of the NH₃ gas or a decrease in the flow rate of the H₂ gas, compared with the conventional apparatus, thus achieving a high degree of freedom of the flow rates of the NH₃ gas and the H₂ gas and expanding process conditions.

### Second Embodiment

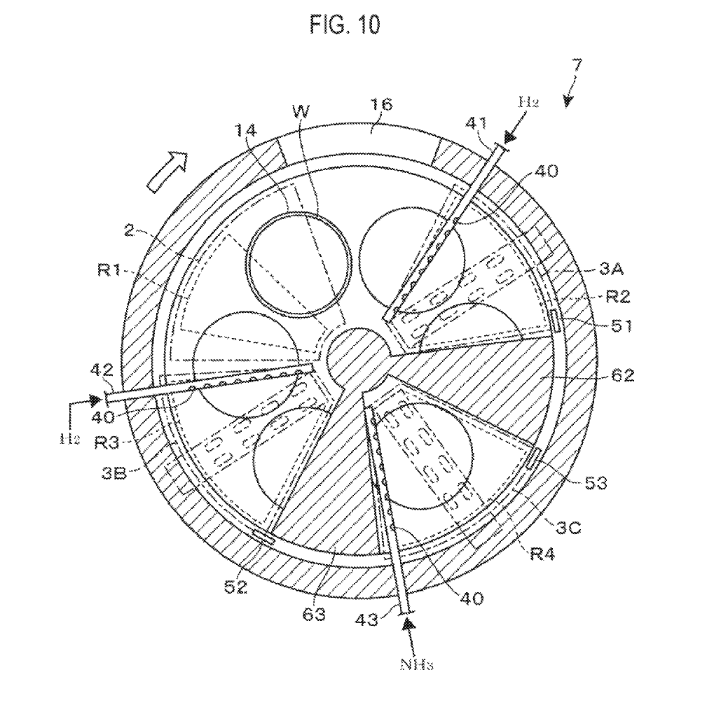

Next, a film forming apparatus 7 of a second embodiment of the present disclosure will be described based on differences from the film forming apparatus 1 of the first embodiment with reference to FIGS. 10 to 12. In the film forming apparatus 7 of this example, a first modification region R2, a reaction region R4, and a second modification region R3 are sequentially arranged along a rotational direction from a downstream side of a gas supply exhaust unit 2 in the rotational direction of a rotary table 12.

A first modification gas discharge part configured as a first gas injector 41 for discharging an H₂ gas toward the downstream side is installed at the end portion of the upstream side of the first modification region R2. A second modification gas discharge part configured as a second gas injector 42 for discharging an H₂ gas toward the upstream side is installed at the end portion of the downstream side of the second modification region R3. Furthermore, a reaction gas discharge part configured as a reaction gas injector 43 for discharging an NH₃ gas toward the upstream side is installed at the end portion of the downstream side of the reaction region R4.

A first exhaust port 51, a third exhaust port 53, and a second exhaust port 52 are formed at an outer side of the rotary table 12 and at positions facing the end portion of the downstream side of the first modification region R2, the end portion of the upstream side of the reaction region R4 and the end portion of the upstream side of the second modification region R3. Similar to the first embodiment, the first to third exhaust ports 51 to 53 are formed to be opened upward below the rotary table 12. Furthermore, a first separation region 62 is formed between the first modification region R2 and the reaction region R4, and a second separation region 63 is formed between the reaction region R4 and the second modification region R3. The first and second separation regions 62 and 63 are configured similarly to the separation region 61 of the first embodiment. The first to third plasma forming units 3A, 3B, and 3C, the first and second gas injectors 41 and 42, the reaction gas injector 43, and the like are similar to those of the first embodiment, and the same components will be denoted by the same reference numerals a description thereof will be omitted.

Even in this embodiment, for example, an H₂ gas is discharged at a flow rate of, for example, 4 l/min from the first and second gas injectors 41 and 42, and an NH₃ gas is discharged at a flow rate of a total of, for example, 1,000 to 4,000 ml/min, for example, 2,000 ml/min, from the reaction gas injector 43. Then, similar to the film forming apparatus 1 of the first embodiment described above, a film forming process of an SiN film is performed.

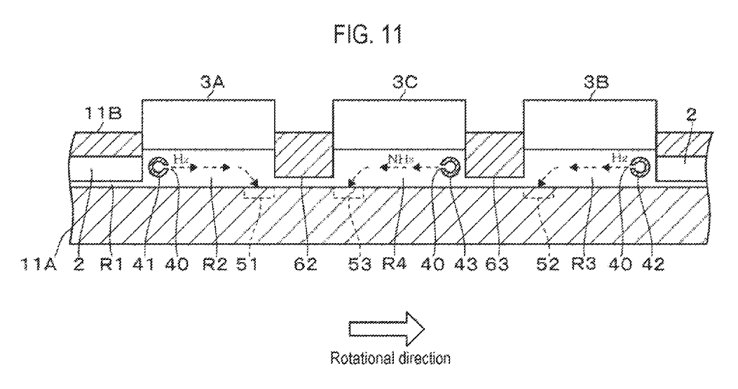

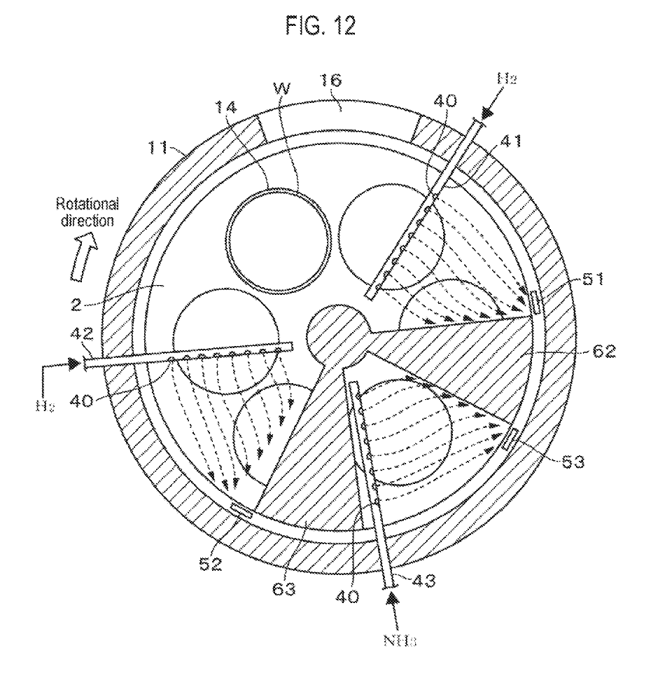

FIGS. 11 and 12 schematically illustrate a state in which a gas is supplied in each part within a vacuum vessel 11. In the first modification region R2, the H₂ gas is discharged in the horizontal direction from the first gas injector 41 installed at the end portion of the upstream side toward the downstream side. The H₂ gas flows toward the first exhaust port 51 formed at the end portion of the downstream side. Thus, the H₂ gas is widely distributed in the entire first modification region R2. For example, a portion of the H₂ gas may be introduced into the first separation region 62. However, since the first separation region 62 has small conductance, the portion of the H₂ gas is returned by virtue of an attractive force of the first exhaust port 51 and exhausted into the first exhaust port 51.

In the reaction region R4, the NH₃ gas is discharged in the horizontal direction from the reaction gas injector 43 installed at the end portion of the downstream side toward the upstream side. The NH₃ gas flows toward the third exhaust port 53 formed at the end portion of the upstream side. Thus, the NH₃ gas flows to be widely spread throughout the reaction region R4. For example, a portion of the NH₃ gas may be introduced into the first separation region 62. However, since the first separation region 62 has small conductance, the portion of the NH₃ gas is returned by virtue of an attractive force of the third exhaust port 53 and exhausted into the third exhaust port 53.

Furthermore, in the second modification region R3, the H₂ gas is discharged in the horizontal direction from the second gas injector 42 installed at the end portion of the downstream side toward the upstream side. The H₂ gas flows toward the second exhaust port 52 formed at the end portion of the upstream side. Thus, the H₂ gas flows to be widely spread throughout the second modification region R3.

In this manner, the gases are discharged from the first gas injector 41 and the reaction gas injector 43 toward the first separation region 62 between the first modification region R2 and the reaction region R4 adjacent to each other, respectively. The NH₃ gas and the H₂ gas are kept from being mixed with each other by the first exhaust port 51 and the third exhaust port 53 and the first separation region 62. That is to say, as described above, the H₂ gas in the first modification region R2 is exhausted by the first exhaust port 51 and the NH₃ gas in the reaction region R4 is exhausted by the third exhaust port 53. For example, even if the H₂ gas tries to move to the side of the reaction region R4, since the H₂ gas is drawn to the third exhaust port 53 formed at an inlet of the reaction region R4, the spreading of the H₂ gas to the reaction region R4 is prevented. Similarly, even if the NH₃ gas in the reaction region R4 tries to move to the side of the first modification region R2, since the NH₃ is drawn to the first exhaust port 51 formed at an inlet of the first modification region R2, the spreading of the NH₃ to the first modification region R2 is prevented.

In addition, since the second separation region 63 is formed between the reaction region R4 and the second modification region R3 which are adjacent to each other, the NH₃ gas and the H₂ gas are kept from being mixed with each other. That is to say, since the NH₃ gas in the reaction region R4 is drawn by the third exhaust port 53, there is almost no NH₃ gas directed to the side of the second modification region R3. For example, even if the NH₃ gas tries to move to the side of the second modification region R3, the NH₃ gas is prevented from entering the side of the second modification region R3 by the second separation region 63. Thus, the spreading of the NH₃ gas to the second modification region R3 is prevented. Similarly, since the H₂ gas in the second modification region R3 is drawn by the second exhaust port 52, there is almost no H₂ gas directed to the side of the reaction region R4. For example, even if the H₂ gas tries to move to the side of the reaction region R4, the H₂ gas is prevented from entering the side of the reaction region R4 by the second separation region 63. Thus, the spreading of the H₂ gas to the reaction region R4 is prevented.

As described above, even in the film forming apparatus 7 of this embodiment, the H₂ gas and the NH₃ gas are kept from being mixed with each other as in the first embodiment. It is therefore possible to form an SiN film having good film quality at a fast deposition rate, to control the film thickness of the wafer W in the radial direction, and to expand process conditions.

In the above, in the film forming apparatus 1 of the first embodiment and the film forming apparatus 7 of the second embodiment, in each of the first and second modification regions R2 and R3 and the reaction region R4, the dedicated exhaust performance is high, and the H₂ gas and the NH₃ gas are kept from being mixed with each other. As such, the separation region 61, the first separation region 62, and the second separation region 63 are additionally formed, but they may not be formed. However, for example, when the flow rate of the NH₃ gas is as large as 1,000 ml/min or more, the separation region 61, the first separation region 62, and the second separation regions 60 may be formed in order to more reliably keep the H₂ gas and the NH₃ gas from being mixed with each other. In addition, the gas injector is not limited to an elongated tubular member as long as it is configured such that the discharge ports are formed along its longitudinal direction and disposed to intersect with the passage region of the wafer W on the rotary table 12. As an example, the gas injector may be a gas supply chamber in which gas discharge ports are formed.

The film forming apparatus of the present disclosure is not limited to the aforementioned embodiments. As an example, the film forming apparatus of the present disclosure may be configured such that the reaction gas discharge part is installed at an end portion of one of the upstream side and the downstream side of the reaction region, the reaction gas is discharged toward the other of the upstream side and the downstream side, and the exhaust port for reaction gas is formed at a position facing an end portion of the other of the upstream side and the downstream side of the reaction region. Further, the film forming apparatus of the present disclosure may be configured such that the modification gas discharge part is installed at an end portion of one of the upstream side and the downstream side of the modification region, the modification gas is discharged toward the other of the upstream side and the downstream side, and the exhaust port for modification gas is formed at a position facing an end portion of the other of the upstream side and the downstream side of the modification region.

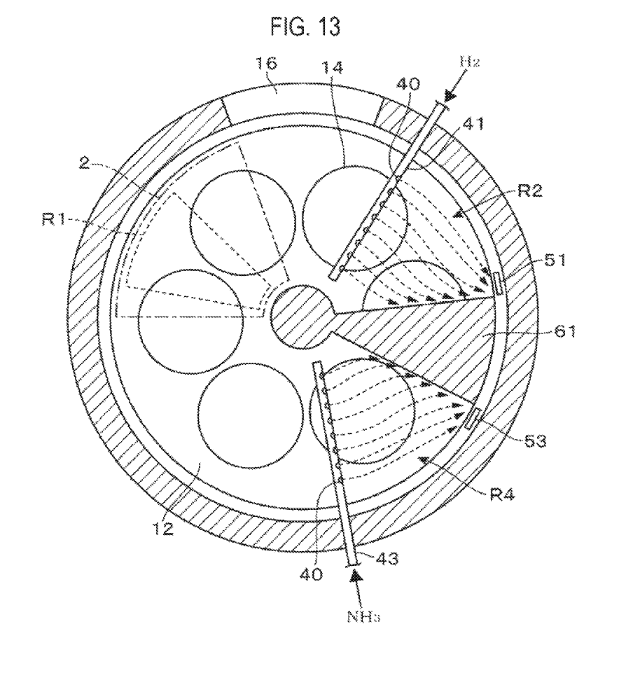

FIG. 13 shows a configuration example in which the reaction region R4 is located at the downstream side of the modification region R2, the reaction gas injector 43 constituting the reaction gas discharge part is installed at the end portion of the downstream side of the reaction region R4 to discharge the reaction gas toward the upstream side, and the third exhaust port 53 for reaction gas is formed at a position facing the end portion of the upstream side of the reaction region R4. Further, in the configuration example of FIG. 13, the first gas injector 41 constituting the modification gas discharge part is installed at the end portion of the upstream side of the first modification region R2 to discharge the modification gas toward the downstream side, and the first exhaust port 51 for modification gas is formed at a position facing the end portion of the downstream side of the first modification region R2.

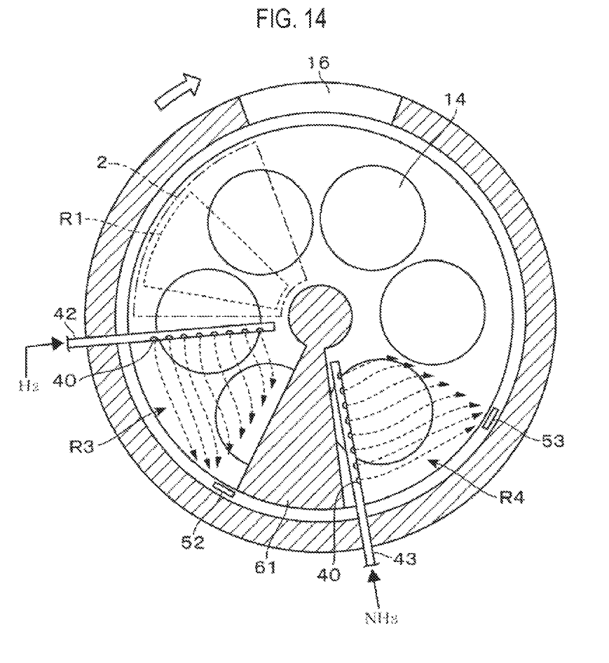

FIG. 14 shows a configuration example in which the reaction region R4 is located at the upstream side of the modification region R3, the reaction gas injector 43 is installed at the end portion of the downstream side of the reaction region R4 to discharge the reaction gas toward the upstream side, and the third exhaust port 53 for reaction gas is formed at a position facing the end portion of the upstream side of the reaction region R4. Further, in the configuration example of FIG. 14, the second gas injector 42 constituting the modification gas discharge part is installed at the end portion of the downstream side of the second modification region R3 to discharge the modification gas toward the upstream side, and the second exhaust port 52 for modification gas is formed at a position facing the end portion of the upstream side of the second modification region R3.

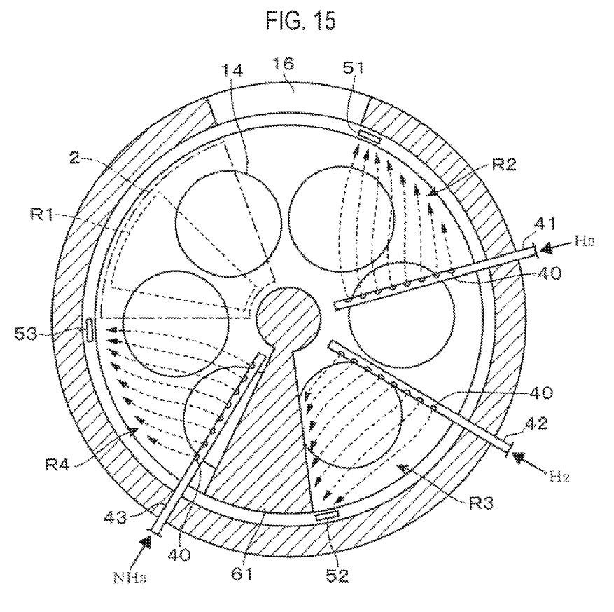

Furthermore, FIG. 15 shows a configuration example in which the reaction region R4 is located at the downstream side of the modification region R3, the reaction gas injector 43 is installed at the end portion of the upstream side of the reaction region R4 to discharge the reaction gas toward the downstream side, and the third exhaust port 53 for reaction gas is formed at a position facing the end portion of the downstream side of the reaction region R4. In addition, in the configuration example of FIG. 15, the second gas injector 42 constituting the modification gas discharge part is installed at the end portion of the upstream side of the second modification region R3 to discharge the modification gas toward the downstream side, and the second exhaust port 52 for modification gas is formed at a position facing the end portion of the downstream side of the second modification region R3.

In the case where the reaction region R4 is located at the upstream side of the second modification region R3 as in the film forming apparatus of the second embodiment, the reaction gas injector 43 may be installed at the end portion of the upstream side of the reaction region R4 to discharge the reaction gas toward the downstream side, and the third exhaust port 53 for reaction gas may be formed at a position facing the end portion of the downstream side of the reaction region R4. Further, the second injector 42 may be installed at the end portion of the downstream side of the modification region R3 and the second exhaust port 52 for modification gas may be formed at a position facing the end portion of the upstream side of the second modification region R3. In this embodiment and the embodiments illustrated in FIGS. 13 to 15, the staying time of the modification gas in the plasma spaces of the modification regions R1 and R2 and the staying time of the reaction gas in the plasma space of the reaction region R4 become long. This provides an effect that the modification process and the nitriding process are sufficiently performed. In this manner, the arrangement positions of the reaction gas injector 43, and the first and second gas injectors 41 and 42 may be suitably changed according to the process conditions.

Furthermore, the purge gas discharge port 23 may be omitted in the gas supply/exhaust unit 2. For example, an additional exhaust port may be installed outside the exhaust port 22. The reaction gas and the modification gas may be exhausted from regions other than the adsorption region R1 through the additional exhaust port, thus separating the atmosphere in the adsorption region R1 from the external atmosphere.

### (Evaluation Test 1)

A simulation was conducted to check an in-plane distribution of a H₂ gas and a NH₃ gas when the H₂ gas is discharged at 4 l/min from each of the first and second gas injectors 41 and 42 and the NH₃ gas is discharged at a flow rate of 1,000 ml/min from the reaction gas injector 43, in the film forming apparatus 1 of the first embodiment. Conditions of this simulation were as follows: the temperature of the rotary table 12: 450 degrees C., and the number of rotations of the rotary table 12: 30 rpm.

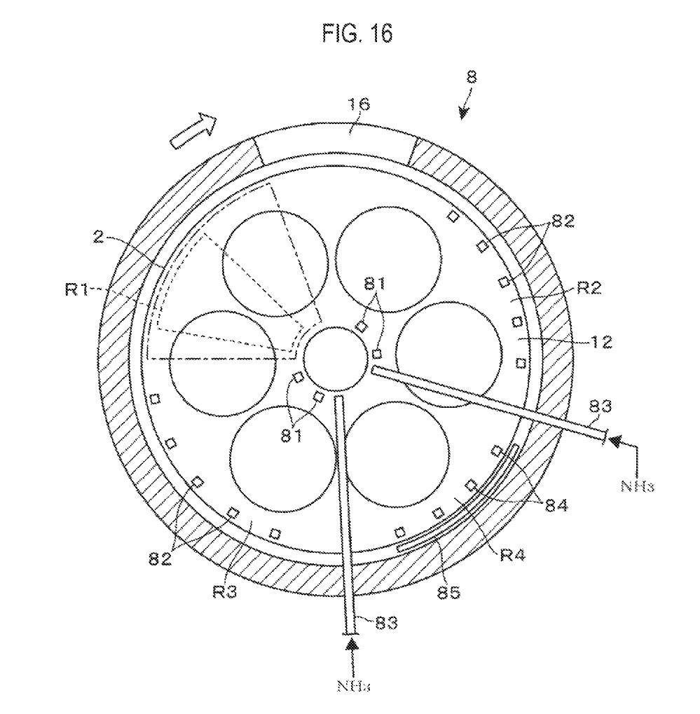

The same simulation was conducted with respect to a film forming apparatus 8 of a comparative model illustrated in FIG. 16 under the same conditions as those of the evaluation test 1. Differences of the film forming apparatus 8 of FIG. 16 from the film forming apparatus 1 of the first embodiment will be briefly described. In this example, the gas supply/exhaust unit 2, the first modification region R2, the reaction region R4, and the second modification region R3 are sequentially arranged from the upstream side of the rotary table 12 in the rotational direction. In the first modification region R2 and the second modification region R3, H₂ gas discharge parts 81 and 82 are installed at the central side and the peripheral side of the rotary table 12, respectively.

In the reaction region R4, reaction gas injectors 83 and 83 configured similarly to that of the first embodiment are respectively installed at the end portion of the upstream side and the end portion of the downstream side in the rotational direction, and NH₃ gas discharge parts 84 are disposed at the peripheral side of the rotary table 12. In addition, a common exhaust port 85 for exhausting the H₂ gas and the NH₃ gas through is formed between the reaction gas injectors 83 and 83. Also in the film forming apparatus 8, the total flow rate of the H₂ gas from the H₂ gas discharge parts 81 and 82, and the total flow rate of the NH₃ gas from the reaction gas injectors 83 and 83 and the NH₃ gas discharge parts 84 were set equal to those of the evaluation test 1.

According to the simulation of the NH₃ concentration, in the apparatus of the present disclosure, it was recognized that the NH₃ concentration is higher in the reaction region R4, compared with the apparatus of the comparative example, which is effective in an increase in deposition rate. In addition, according to the simulation of the H₂ concentration, in the apparatus of the present disclosure, it was recognized that the H₂ concentration in the reaction region R4 is very low, which makes it possible to separate the H₂ gas and the NH₃ gas between the first and second modification regions R2 and R3 and the reaction region R4, compared with the apparatus of the comparative example. Moreover, in the apparatus of the present disclosure, it is understood that the NH₃ concentration in the first and second modification regions R2 and R3 are very low, which is effective in lowering an etching rate, compared with the apparatus of the comparative example.

### (Evaluation Test 2)

An evaluation was conducted with respect to a deposition rate when the H₂ gas is discharged at 4 l/min from each of the first and second gas injectors 41 and 42 and the NH₃ gas is discharged from the reaction gas injector 43 to form an SiN film, in the apparatus of the present disclosure. Furthermore, an evaluation was conducted with respect to an etching rate when performing a wet etching on the SiN film thus obtained using a hydrofluoric acid solution. Film formation conditions of the SiN film were as follows: the temperature of the rotary table 12: 450 degrees C., the number of rotations of the rotary table 12: 30 rpm, the process pressure: 267 Pa (2 Torr), and the supply flow rate of the NH₃ gas is changed within a range of 0 to 1,600 ml/min. In addition, the evaluation test 2 was similarly conducted using the apparatus of the comparative example.

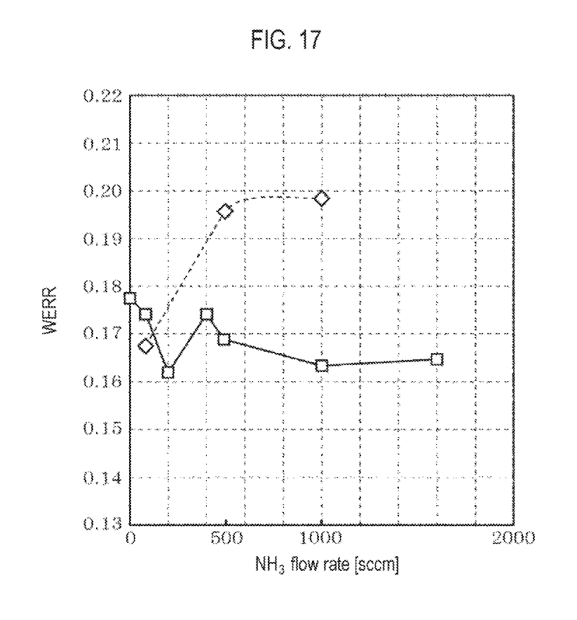

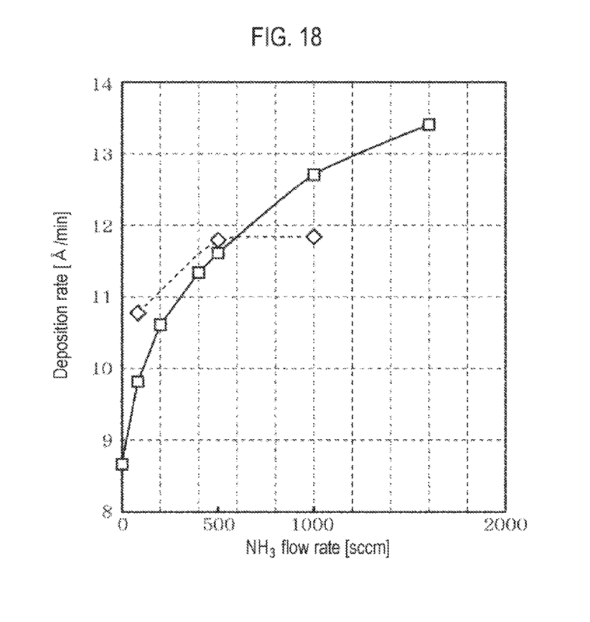

The etching rate is illustrated in FIG. 17 and the deposition rate is illustrated in FIG. 18. In FIG. 17, the vertical axis represents an etching rate ratio (WERR), the horizontal axis represents a flow rate of the NH₃ gas. Also, in FIG. 17, the data of the apparatus of the present disclosure is plotted by symbol □ and the data of the apparatus of the comparative example is plotted by symbol ⋄. Furthermore, in FIG. 18, the vertical axis represents a deposition rate, the horizontal axis represents a flow rate of the NH₃ gas. Also, in FIG. 18, the data of the apparatus of the present disclosure is plotted by symbol □, and the data of the apparatus of the comparative example is plotted by symbol ⋄. In addition, assuming that an etching rate when a thermal oxide film was wet-etched using a hydrofluoric acid solution under the same conditions is 1, the etching rate in FIG. 17 is illustrated as a relative value. The etching rate ratio (WERR) can be expressed as follows.

WERR=Wet etching rate of nitride film/Wet etching rate of thermal oxide film

Regarding the etching rate ratio as an index of film quality, it was recognized from FIG. 17 that, in the apparatus of the present disclosure, the low etching rate can be secured even if the flow rate of the NH₃ gas is increased, in particular, the etching rate ratio was further lowered to 0.17 or lower when the flow rate of the NH₃ gas is 500 ml/min or more. Meanwhile, it was confirmed that, in the apparatus of the comparative example, the etching rate ratio was 0.17 or lower when the flow rate of the NH₃ gas is 100 ml/min or lower, while the etching rate ratio was rapidly increased with an increase in the flow rate of the NH₃ gas. The reason for this is as follows. In the apparatus of the comparative example, the NH₃ gas and the H₂ gas were mixed with each other in the modification region as the flow rate of the NH₃ gas increases, which allows the reaction based on the NH₃ gas to be performed earlier than the modification process based on the H₂ gas. As a result, the modification process was performed inefficiently.

Regarding the deposition rate, it was recognized from FIG. 18 that, in the apparatus of the present disclosure, the deposition rate is rapidly enhanced with an increase in the flow rate of the NH₃ gas, whereas in the apparatus of the comparative example, when the flow rate of the NH₃ gas is 500 ml/min or more, the deposition rate is almost not changed. The reason for this is as follows. In the apparatus of the comparative example, due to a positional relationship between the gas supply part and the exhaust port, the NH₃ gas rapidly flown as it is toward the exhaust port so that an exhaust amount of the NH₃ gas was increased regardless of an increase in the flow rate of the NH₃ gas.

As described above, it was recognized that, in the film forming apparatus 1 of the present disclosure, when the flow rate of the NH₃ gas is 300 ml/min, the etching rate is lower than and the deposition rate is substantially equal to those of the apparatus of the comparative example. Furthermore, it was confirmed that, when the flow rate of the NH₃ gas is 300 ml/min or more, the deposition rate is higher than and the etching rate is lower than those of the apparatus of the comparative example. As described above, it is understood that, according to the present disclosure, the low etching rate can be achieved while the high deposition rate is secured, by increasing the flow rate of the NH₃ gas. Thus, it was confirmed that the film forming apparatus 1 of the present disclosure is effective for a process in which the flow rate of the NH₃ gas is 300 ml/min or more.

Moreover, similar to the apparatus of the comparative example, even in an apparatus in which the NH₃ gas and the H₂ gas are exhausted from the common exhaust port 85, the etching rate of 0.18 or lower is secured when the flow rate of the NH₃ gas is 200 ml/min. From this, it is understood that, similar to the apparatus of the present disclosure, in an apparatus in which the NH₃ gas and the H₂ gas are respectively exhausted from the dedicated exhaust ports, the NH₃ gas and the H₂ gas are sufficiently kept from being mixed with each other even in a configuration in which the separation region is not formed between the supply region of the NH₃ gas and the supply region of the H₂ gas. Thus, even with the configuration in which the separation region is not formed, if the flow rate of the NH₃ gas is 300 ml/min or more, it can be said that it is possible to secure a fast deposition rate and a low etching rate, compared with the apparatus of the comparative example.

### (Evaluation Test 3)

An evaluation was conducted with respect to a film thickness distribution when the H₂ gas is discharged at 4 l/min from each of the first and second gas injectors 41 and 42, and the NH₃ gas is discharged from the reaction gas injector 43 to form an SiN film, in the apparatus of the present disclosure. Film formation conditions of the SiN film are as follows: the temperature of the rotary table 12: 450 degrees C., the number of rotations of the rotary table 12 is 30 rpm, and the process pressure: 267 Pa (2 Torr), and the supply flow rate of the NH₃ gas is changed in the first discharge region 431 and the second discharge region 432.

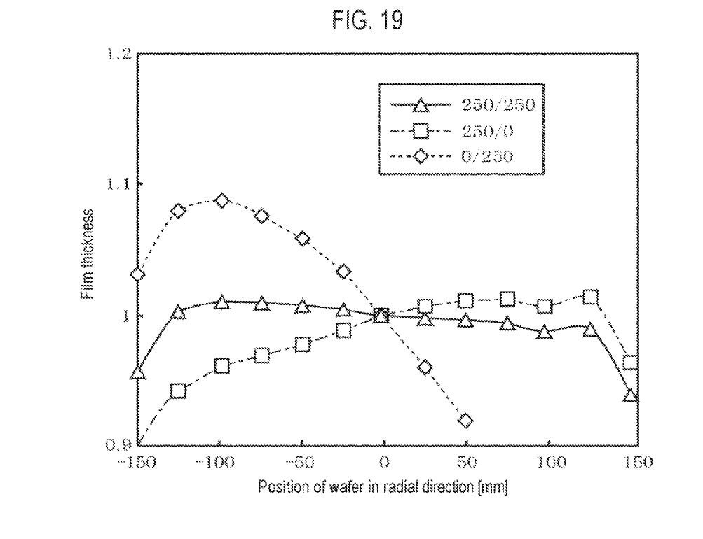

The results are illustrated in FIG. 19. In FIG. 19, the vertical axis represents a film thickness and the horizontal axis represents a position of the wafer W in the radial direction. The position of the wafer W in the radial direction is 0 at the wafer center, the rotation central side of the rotary table 12 is +150 mm, and the peripheral side of the rotary table 12 is −150 mm. Assuming that the flow rate of the NH₃ gas in the first discharge region 431 is F1 and the flow rate of the NH₃ gas in the second discharge region 432 is F2, the case of F1/F2=250 sccm/250 sccm is plotted using the symbol Δ, the case of F1/F2=250 sccm/0 sccm is plotted using the symbol □, and the case of F1/F2 is 0 sccm/250 sccm is plotted using the symbol ⋄. The film thickness is an arbitrary constant normalized so that the film thickness at the wafer center becomes 1.

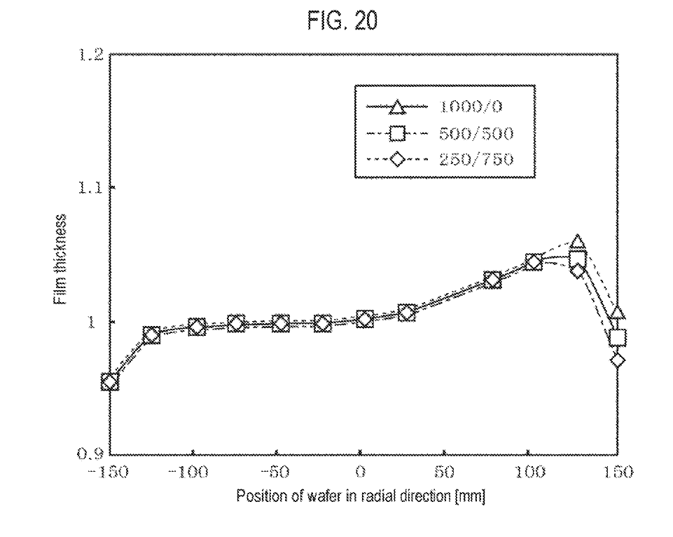

Furthermore, the evaluation test 3 was similarly conducted using the apparatus of the comparative example. The results are illustrated in FIG. 20. As in FIG. 19, in FIG. 20, the vertical axis represents a film thickness, and the horizontal axis represents a position of the wafer W in the radial direction. Assuming that the total flow rate of the NH₃ gas from the reaction gas injectors 83 and 83 is F3 and the total flow rate of the NH₃ gas from the discharge parts 84 is F4, the case of F3/F4=1,000 sccm/0 sccm is plotted using the symbol Δ, the case of F3/F4=500 sccm/500 sccm is plotted using the symbol □, and the case of F3/F4=250 sccm/750 sccm are plotted using the symbol ⋄.

From FIG. 19 illustrating the results of the apparatus of the present disclosure, it was recognized that, when the flow rate of the NH₃ gas from the first discharge region 431 at the leading end side of the reaction gas injector 43 is increased, the film thickness at the rotation central side of the rotary table 12 is increased, and when the flow rate of the NH₃ gas from the second discharge region 432 at the base end side of the reaction gas injector 43 is increased, the film thickness at the peripheral side of the rotary table 12 is increased. Thus, it is understood that, by changing the flow rates of the NH₃ gas in the first discharge region 431 and the second discharge region 432, the film thickness distribution of the wafer W in the radial direction is changed and thus the film thickness controllability of the wafer W in the radial direction is good. In contrast, in FIG. 20 illustrating the results of the apparatus of the comparative example, it was confirmed that, even when the flow rates of the NH₃ gas from the reaction gas injector 83 and the discharge parts 84 are changed, the film thickness distribution of the wafer W in the radial direction is almost the same and it is difficult to control the film thickness.

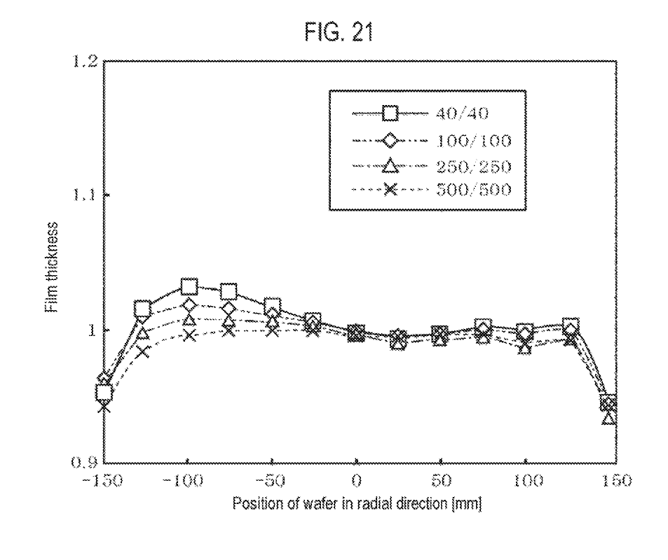

Furthermore, in the apparatus of the present disclosure, an SiN film was formed by changing the total flow rate of the NH₃ gas, and a film thickness thereof was evaluated. The results are illustrated in FIG. 21. In FIG. 21, the vertical axis represents a film thickness and the horizontal axis represents a position of the wafer W in the radial direction. Assuming that the flow rate of the NH₃ gas in the first discharge region 431 is F1 and the flow rate of the NH₃ gas in the second discharge region 432 is F2, the case of F1/F2=40 sccm/40 sccm is plotted using the symbol □, the case of F1/F2 is 100 sccm/100 sccm is plotted using the symbol ⋄, the case of F1/F2=250 sccm/250 sccm is plotted using the symbol Δ, and the case of F1/F2 is 500 sccm/500 sccm is plotted using the symbol x.

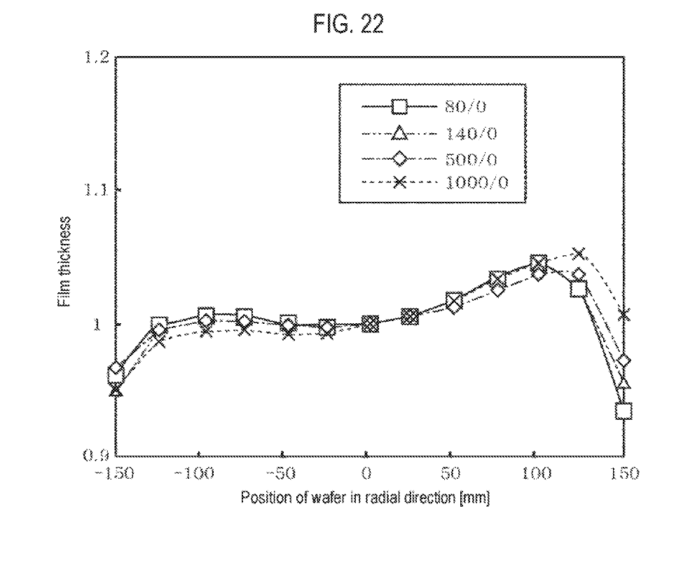

Furthermore, a film thickness of the SiN film was also evaluated using the apparatus of the comparative example when the total flow rate of the NH₃ gas was changed. The results are illustrated in FIG. 22. In FIG. 22, the vertical axis represents a film thickness, and the horizontal axis represents a position of the wafer W in the radial direction. Assuming that the total flow rate of the NH₃ gas from the reaction gas injectors 83 and 83 is F3 and the total flow rate of the NH₃gas from the discharge parts 84 is F4, the case of F3/F4=80 sccm/0 sccm is plotted using the symbol □, the case of F3/F4=140 sccm/0 sccm is plotted using the symbol Δ, the case of F3/F4=500 sccm/0 sccm is plotted using the symbol ⋄, and the case of F3/F4 is 1,000 sccm/0 sccm is plotted using the symbol x.

From FIG. 21 illustrating the results of the apparatus of the present disclosure, it was recognized that, by increasing the flow rate of the NH₃ gas, the film thickness can be controlled to have a substantially uniform distribution in a range of −100 mm to +100 mm in a position of the wafer W in the radial direction. This shows that the in-plane uniformity of the film thickness is improved. It is understood that an SiN film having good in-plane uniformity of the film thickness can be formed at a fast deposition rate while maintaining a low etching rate. In contrast, in FIG. 22 illustrating the results of the apparatus of the comparative example, it was confirmed that, even when the flow rate of the NH₃ gas is increased, the film thickness distribution is almost the same, and it is difficult to improve the in-plane uniformity of the film thickness.

According to the present disclosure in some embodiments, a modification gas containing hydrogen supplied to a modification region is exhausted from an exhaust port formed in the modification region, and a reaction gas containing a nitrogen-containing gas supplied to a reaction region is exhausted from an exhaust port formed in the reaction region. Therefore, so-called dedicated exhaust performance is high in each of the modification and reaction regions. This suppresses the modification gas and the reaction gas from being mixed with each other between the modification region and the reaction region. Thus, even when the supply flow rate of the reaction gas to the reaction region is increased, a high modification efficiency can be secured in the modification region. Furthermore, in the reaction region, a deposition rate is increased with an increase in the flow rate of the reaction gas. As a result, it is possible to form a high quality silicon nitride film having a low etching rate at a fast deposition rate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus for forming a silicon nitride film on a substrate by revolving the substrate mounted on a rotary table inside a vacuum vessel while rotating the rotary table and supplying a raw material gas containing silicon and a nitrogen-containing gas to each of a plurality of regions formed to be separated from each other on the rotary table in a circumferential direction, comprising:
a raw material gas supply part installed to face the rotary table and including a discharge part configured to discharge the raw material gas and an exhaust port configured to surround the discharge part;
a reaction region and a modification region of the plurality of regions which are formed apart from the raw material gas supply part in a rotational direction of the rotary table and are formed apart from each other in the rotational direction of the rotary table;
a reaction gas discharge part installed at an end portion of one of an upstream side and a downstream side of the reaction region and configured to discharge a reaction gas containing the nitrogen-containing gas toward the other of the upstream side and the downstream side of the reaction region;
a modification gas discharge part installed at an end portion of one of an upstream side and a downstream side of the modification region and configured to discharge a modification gas containing a hydrogen gas toward the other of the upstream side and the downstream side of the modification region;
a reaction gas exhaust port formed at an outer side of the rotary table and at a position facing an end portion of the other of the upstream side and the downstream side of the reaction region;
a modification gas exhaust port formed at an outer side of the rotary table and at a position facing an end portion of the other of the upstream side and the downstream side of the modification region; and
a plasma generation part for reaction gas and a plasma generation part for modification gas which are configured to activate gases respectively supplied to the reaction region and the modification region,
wherein each of the reaction gas discharge part and the modification gas discharge part is constituted by a gas injector having discharge ports formed along a longitudinal direction, and disposed to intersect with a passage region of the plurality of regions through which the substrate mounted on the rotary table passes.

2. The apparatus of claim 1, wherein the apparatus has:
a configuration in which the reaction gas discharge part is installed at an end portion of the upstream side of the reaction region and the modification gas discharge part is installed at an end portion of the upstream side of the modification region, or
a configuration in which the reaction gas discharge part is installed at an end portion of the downstream side of the reaction region and the modification gas discharge part is installed at an end portion of the downstream side of the modification region.

3. The apparatus of claim 1, wherein the apparatus has:
a configuration in which the reaction region is located at the downstream side of the modification region, the reaction gas discharge part is installed at an end portion of the downstream side of the reaction region, and the modification gas discharge part is installed at an end portion of the upstream side of the modification region, or
a configuration in which the reaction region is located at the upstream side of the modification region, the reaction gas discharge part is installed at an end part of the upstream side of the reaction region, and the modification gas discharge part is installed at an end portion of the downstream side of the modification region.

4. The apparatus of claim 1, wherein the modification region includes a first modification region and a second modification region formed at the downstream side of the rotary table with respect to the first modification region.

5. The apparatus of claim 4, wherein the second modification region is formed adjacent to the first modification region,
wherein the first modification region includes a first modification gas discharge part installed at a downstream side of the first modification region, and
wherein the second modification region includes a second modification gas discharge part installed at an upstream side of the second modification region.

6. The apparatus of claim 1, wherein a flow rate of the nitrogen-containing gas supplied to the reaction region is 300 ml/min or more.

7. The apparatus of claim 1, wherein a gas discharge direction of the gas injector is set to be oriented between an upwardly 45 degree-inclined orientation and a downwardly 45-degree inclined orientation with respect to a direction parallel to an upper surface of the rotary table.
